(19) United States
(12) Patent Application Publication
(10) Pub. No.: US 2011/0117751 A1
(43) Pub. Date: May 19, 2011

(54) NON-SELECTIVE OXIDE ETCH WET CLEAN COMPOSITION AND METHOD OF USE

(75) Inventors: Prerna Sonthalia, Mumbai (IN); Emanuel I. Cooper, Scarsdale, NY (US); David Minsek, New Milford, CT (US); Peng Zhang, Montvale, NJ (US); Melissa A. Petruska, Newtown, CT (US); Brittany Serke, Rochester, NY (US); Trace Quentin Hurd, Brookfield, CT (US)

(73) Assignee: ADVANCED TECHNOLOGY MATERIALS, INC., Danbury, CT (US)

(21) Appl. No.: 12/921,262

(22) PCT Filed: Mar. 6, 2009
(86) PCT No.: PCT/US2009/036366

§ 371 Date: Jan. 13, 2011

Related U.S. Application Data
(60) Provisional application No. 61/034,891, filed on Mar. 7, 2008.
(60) Provisional application No. 61/077,155, filed on Jun. 30, 2008.

(51) Int. Cl. H01L 21/306; C09K 13/00; C09K 13/06

(52) U.S. Cl. 438/753; 252/79.1; 252/79.4; 257/E21.228

(57) ABSTRACT

Composition and method to remove undoped silicon-containing materials from microelectronic devices at rates greater than or equal to the removal of doped silicon-containing materials.

### FIELD

The present invention relates generally to compositions that selectively remove undoped silicon-containing materials relative to doped silicon-containing materials.

### DESCRIPTION OF THE RELATED ART

Various silicon-containing films such as thermal oxide (ThOx), CVD-TEOS, borophosphosilicate glass (BPSG), borosilicate glass (BSG), spin-on dielectrics (SOD) and phosphosilicate glass (PSG) are used in semiconductor manufacturing. Two of the most common types are ThOx and BPSG. Thermal oxide is typically composed of pure silicon dioxide and is utilized when an insulating layer is required. For example, thin “gate” layers of thermal silicon oxide are often utilized to separate conducting layers from each other. BPSG layers are comprised of silicon oxide which has been doped with boron and phosphorus. These layers serve the purpose of “gettering” alkali metal ion contaminants which could otherwise migrate into underlying layers and adversely affect electrical properties of the layer materials, causing device reliability degradation.

These silicon-containing materials are formed in several patterned layers on the substrate surface and are engineered to have increasingly high-aspect ratios and small dimensions. During manufacturing, post-etch or post-ash residue must be removed from the patterned surface without damaging the patterned materials. For example, a residue (predominantly ThOx) at the bottom of a contact hole requires removal with minimum etching of the less dense doped silicon-containing oxides. Disadvantageously, prior art removal compositions and methods designed for etch selectivity and/or post-etch or post-ash residue removal have favored the removal of doped silicon-containing materials (e.g., BPSG) over non-doped silicon-containing materials (e.g., ThOx). This results in a pattern where the critical dimensions have been detrimentally altered.

This disclosure focuses on the development of “liquid contact-cleaners” for doped and undoped oxides with unique etch selectivities, low etch-rates and aggressive cleaning capacities.

### SUMMARY

The present invention generally relates to compositions that remove non-doped silicon-containing materials at rates greater than or substantially equal to that of doped silicon-containing materials. In a preferred embodiment, compositions and methods are disclosed to remove post-etch and/or post-ash residue from the surface of a microelectronic device without overetching doped silicon-containing materials relative to undoped silicon-containing materials also present on said device.

In one aspect, a wet clean composition is described, said composition comprising at least one fluoride source, at least one glycol solvent, at least one chelating agent and at least one polymeric species, wherein the composition is substantially devoid of added water.

In another aspect, a wet clean composition is described, said composition comprising at least one fluoride source, at least one glycol solvent, at least one chelating agent, at least one polymeric species, and at least one long chain alkyl quaternary ammonium compound, wherein the composition is substantially devoid of added water.

In still another aspect, a wet cleaning composition is described, said composition comprising ammonium fluoride, ethylene glycol, iminodiacetic acid, and polyethylenimine polymer.

In yet another aspect, a wet cleaning composition is described, said composition comprising ammonium fluoride, ethylene glycol, iminodiacetic acid, polyethylenimine polymer, and long chain alkyl quaternary ammonium compound.

Another aspect relates to a method of selectively removing undoped silicon-containing material relative to doped silicon-containing material, said method comprising contacting a microelectronic device having undoped and doped silicon-containing materials thereon with a wet clean composition under contacting conditions, wherein the wet clean composition comprises at least one fluoride source, at least one glycol solvent, at least one chelating agent and at least one polymeric species, wherein the composition is substantially devoid of water. The composition may further comprise at least one long chain alkyl quaternary ammonium compound.

Still another aspect relates to a method of removing post-etch and/or post-ash residue from a microelectronic device, said method comprising contacting a microelectronic device having post-etch and/or post-ash residue thereon with a wet clean composition under contacting conditions, wherein the wet clean composition comprises at least one fluoride source, at least one glycol solvent, at least one chelating agent and at least one polymeric species, and wherein the etch rate of undoped silicon-containing materials present on said device is greater than or substantially equal to the etch rate of doped silicon-containing materials present on said device, and wherein the composition is substantially devoid of water. The composition may further comprise at least one long chain alkyl quaternary ammonium compound.

In another aspect, a kit is described, wherein said kit comprises, in one or more containers, one or more of the following reagents for forming a composition, wherein said composition comprises at least one fluoride source, at least one glycol solvent, at least one chelating agent and at least one polymeric species, wherein the kit is adapted to form a composition suitable for removing post-etch residue, post-ash residue, doped silicon-containing material, undoped silicon-containing material, and combinations thereof.

Other aspects, features and advantages will be more fully apparent from the ensuing disclosure and appended claims.

### BRIEF DESCRIPTION OF THE DRAWINGS

FIG. 1 illustrates the C/S SEM image of a stack, which consists of a ˜500 Å of PE-CVD SiN base with the “walls” made of 4 KÅ TEOS and 4.5 KÅ PSG, processed with formulation B at 45° C. for 4 min.

FIG. 2 illustrates the C/S SEM images of a stack similar to that in FIG. 1 that has been cleaned using Formulation B (45° C./4 min).

FIG. 3 illustrates the C/S SEM images of a stack similar to that in FIG. 1 that has been cleaned using dilute HF (45° C./4 min).

### DETAILED DESCRIPTION AND PREFERRED EMBODIMENTS THEREOF

The present invention generally relates to wet clean compositions and methods for the removal of post-etch and/or post-ash residue from a microelectronic device, wherein the etch rate of non-doped silicon-containing materials present on said device is greater than or substantially equal to the etch rate of doped silicon-containing materials also present on said device. Preferably, the wet clean compositions have minimal impact on the contact profile or the critical dimensions of a pattern, are compatible with silicon and metals, and the post-process contact surface is hydrophobic or hydrophilic and stable.

For ease of reference, “microelectronic device” corresponds to semiconductor substrates, solar cells (photovoltaics), flat panel displays, and microelectromechanical systems (MEMS), manufactured for use in microelectronic, integrated circuit, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

As used herein, “about” is intended to correspond to ±5% of the stated value.

As used herein, “undoped silicon-containing materials” or “higher density dielectric materials” correspond to silicate materials that are substantially devoid of “dopants” such as boron, boron difluoride, phosphorous, arsenic, gallium, antimony, carbon, nitrogen, and indium. Examples of undoped silicon-containing materials include, but are not limited to, thermal oxides, high density plasma deposited oxides, and TEOS, regardless of how deposited. “Doped silicon-containing materials” or “lower density dielectric materials” correspond to silicon oxide materials that include “dopants” including, but not limited to, BSG, PSG, BPSG, FSG (fluorosilicate glass), SiCOH, SiON, SiCON, carbon-doped oxides (CDO), and SOD. It should be appreciated that the dielectric materials may further include germanium.

As used herein, “SOD” and spin-on glass (SOG) are synonymous.

As defined herein, “substantially devoid” corresponds to less than about 2 wt. %, more preferably less than 1 wt. %, and most preferably less than 0.1 wt. % of the composition, based on the total weight of said composition.

As defined herein, “added water” corresponds to water added by the user or the producer of the composition of the invention. Added water does not correspond to water often found in the commercial chemicals mixed together to form the composition of the invention, or hygroscopic water.

As defined herein, “substantially equal” corresponds to an etch rate (in Å min⁻¹) of doped silicon-containing materials that is the same as or ±40% of the etch rate of undoped silicon-containing materials.

Compositions may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

In one aspect, a wet clean composition comprising, consisting of, or consisting essentially of at least one fluoride source, at least one organic solvent, at least one chelating agent and at least one polymeric species is described, wherein the composition is substantially devoid of added water. In a preferred embodiment, a wet clean composition comprising, consisting of, or consisting essentially of at least one fluoride source, at least one glycol solvent, at least one chelating agent and at least one polymeric species is described, wherein the composition is substantially devoid of added water.

The at least one fluoride source may comprise a species selected from the group consisting of xenon difluoride; pentamethyldiethylenetriammonium trifluoride; ammonium bifluoride; triethylamine trihydrofluoride; alkyl hydrogen fluoride (NRH₃F), wherein each R is independently selected from hydrogen and C₁-C₄ alkyl (e.g., methyl, ethyl, propyl, butyl); dialkylammonium hydrogen fluoride (NR₂H₂F), wherein each R is independently selected from hydrogen and C₁-C₄ alkyl; trialkylammonium hydrogen fluoride (NR₃HF), wherein each R is independently selected from hydrogen and C₁-C₄ alkyl; trialkylammonium trihydrogen fluoride (NR₃:3HF), wherein each R is independently selected from hydrogen and C₁-C₄ alkyl; ammonium fluorides of the formula R₄NF, wherein each R is independently selected from hydrogen, C₁-C₄ alkyl, and C₁-C₄ alkanol (e.g., methanol, ethanol, propanol, butanol) such as ammonium fluoride, tetramethylammonium fluoride, triethanolammonium fluoride, tetraethylammonium fluoride; and combinations thereof.

The at least one glycol solvent may comprise a glycol solvent selected from the group consisting of ethylene glycol, propylene glycol, diethylene glycol, dipropylene glycol, glycerol, a monoglyceride, a diglyceride, a glycol ether, and combinations thereof, wherein the glycol ether comprises a species selected from the group consisting of diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof.

The at least one chelating agent may comprise β-diketonate compounds such as acetylacetonate, 1,1,1-trifluoro-2,4-pentanedione, and 1,1,1,5,5,5-hexafluoro-2,4-pentanedione; carboxylates such as formate and acetate and other long chain carboxylates; amines and amino acids such as glycine, serine, proline, leucine, alanine, asparagine, aspartic acid, glutamine, valine, and lysine; a polyprotic acid selected from the group consisting of iminodiacetic acid (IDA), malonic acid, oxalic acid, succinic acid, boric acid, nitrilotriacetic acid, malic acid, citric acid, acetic acid, maleic acid, 2,4-pentanedione, benzalkonium chloride, 1-imidazole; and combinations thereof. Additional chelating agents include phosphonic acid, phosphonic acid derivatives such as hydroxyethylidene diphosphonic acid (HEDP), 1-hydroxyethane-1,1-diphosphonic acid, nitrilo-tris(methylenephosphonic acid), etidronic acid, ethylenediamine, ethylenediaminetetraacetic acid (EDTA), and (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates (R¹(CH₂CH₂O)₂NR²CS₂Na) with one alkyl group (R²=hexyl, octyl, deceyl or dodecyl) and one oligoether (R¹(CH₂CH₂O)₂, where R¹=ethyl or butyl), ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid, sodium triphosphate penta basic, and combinations thereof with each other or the β-diketonate compounds, carboxylates, amines and amino acids or polyprotic acids defined above.

Although not wishing to be bound by theory, it is thought that the at least one polymeric species is added for better surface coverage, leading to improved surface protection and more controlled etch rates for the films. Preferably the polymeric species are cationic surfactants and may comprise at least one of a polypropylenimine dendrimer (e.g., polypropylenimine tetraamine dendrimer, polypropylenimine octaamine dendrimer, polypropylenimine hexadecaamine dendrimer, polypropylenimine dotriacontaamine dendrimer, polypropylenimine tetrahexacontaamine dendrimer), a poly(vinyl amine), a polyamine, a polyimidamine, a polyethylimine, a polyamidamine, a poly quaternary amine, a polyvinyl amide, a polyacrylamide, a linear or branched polyethylenimine, and copolymers that may comprise or consist of the aforementioned homopolymers, wherein the copolymers may or may not be cationic. When the polymeric species comprises polyethylenimine it may be selected from the group consisting of polyethylenimine, an ethylenediamine-ethyleneimine copolymer, a hydroxylated polyethylenimine, a modified polyethylenimine, and combinations thereof. Examples of polymeric species include Lupasol® (BASF) and Epomin® (Nippon Shokubai).

Preferably, the pH of the wet clean compositions are in the range from about 4 to about 9, preferably about 5 to about 9.

In one embodiment, the composition may further comprise, consist of or consist essentially of at least one amine including, but not limited to, dicyclohexylamine, pentamethyldiethylenetriamine, diglycolamine, pyridine, 2-ethylpyridine, 2-methoxypyridine and derivatives thereof such as 3-methoxypyridine, 2-picoline, pyridine derivatives, dimethylpyridine, piperidine, piperazine, triethylamine, triethanolamine, ethylamine, methylamine, isobutylamine, tert-butylamine, tributylamine, dipropylamine, dimethylamine, monoethanolamine, pyrrole, isoxazole, 1,2,4-triazole, bipyridine, pyrimidine, pyrazine, pyridazine, quinoline, isoquinoline, indole, imidazole, 1-methylimidazole, diisopropylamine, diisobutylamine, aniline, aniline derivatives or combinations thereof.

In one embodiment, the wet clean composition includes the following components in the weight percent ratios provided:

| | | Preferred weight % | Most preferred weight |
|---|---|---|---|
| Component | weight % ratio | ratio | % ratio |
| chelating agent(s) to | about 0.2 to about 0.8 | about 0.45 to about 0.7 | about 0.54 to about |
| fluoride source(s) | | | 0.64 |
| Glycol solvent(s) to | about 100 to about | about 300 to about 500 | about 350 to about 450 |
| fluoride source(s) | 600 | | |
| Polymeric species to | about 0.01 to about | about 0.1 to about 0.3 | about 0.15 to about 0.2 |
| fluoride source(s) | 0.5 | | |

In another embodiment, the wet clean composition includes the following components in the weight percent ratios provided:

| | | Preferred weight % | Most preferred weight |
|---|---|---|---|
| Component | weight % ratio | ratio | % ratio |
| chelating agent(s) to | about 0.001 to about | about 0.01 to about | about 0.03 to about |
| fluoride source(s) | 0.3 | 0.25 | 0.15 |
| Glycol solvent(s) to | about 1 to about 30 | about 5 to about 25 | about 10 to about 15 |
| fluoride source(s) | | | |
| Polymeric species to | about 0.001 to about | about 0.01 to about 0.2 | about 0.01 to about |
| fluoride source(s) | 0.3 | | 0.04 |

In one embodiment, the wet clean composition comprises, consists of or consists essentially of ammonium fluoride, ethylene glycol, iminodiacetic acid, and a polyethylenimine polymer. Preferably, the polyethylenimine polymer comprises Lupasol® G20.

In another embodiment the formulation further comprises a long chain alkyl quaternary ammonium compound, which is added to the composition to impart a hydrophobic surface and increased queue time for the next integration step. Preferably, the long chain alkyl quaternary ammonium compound comprises a tricaprylmethylammonium cation [C₂₅H₅₄N⁺] combined with a chloride anion, although other tricapryl and trioctyl methylammonium cation [C₂₅H₅₄N⁺]-containing compounds and salts with one or two long alkyl chains, including cetyltrimethylammonium bromide (CTAB), dodecyltrimethyl ammonium chloride, hexadecyltrimethylammonium chloride, dioctyl dimethyl ammonium chloride, and poly(allyldimethylammonium) chloride are also contemplated. The long chain alkyl group may be saturated or unsaturated. In one embodiment, the long chain alkyl quaternary ammonium compound comprises Aliquat 336 (trademark of Cognis Corp). Accordingly, in a particularly preferred embodiment, the composition comprises, consists of or consists essentially of at least one fluoride source, at least one glycol solvent, at least one chelating agent, at least one polymeric species, and at least one long chain quaternary ammonium compound. For example, the composition may comprise, consist of, or consist essentially of ammonium fluoride, ethylene glycol, iminodiacetic acid, a polyethylenimine polymer, and a long chain alkyl quaternary ammonium compound. Preferably, the polyethylenimine polymer comprises Lupasol® G20. In another preferred embodiment, the long chain alkyl quaternary ammonium compound comprises Aliquat 336. The wet clean composition may include the following components in the weight percent ratios provided:

| | | Preferred weight % | Most preferred weight |
|---|---|---|---|
| Component | weight % ratio | ratio | % ratio |
| chelating agent(s) to | about 0.2 to about 0.8 | about 0.45 to about 0.7 | about 0.54 to about |
| fluoride source(s) | | | 0.64 |
| Glycol solvent(s) to | about 100 to about | about 300 to about 500 | about 350 to about 450 |
| fluoride source(s) | 600 | | |
| Polymeric species to | about 0.01 to about | about 0.1 to about 0.3 | about 0.15 to about 0.2 |
| fluoride source(s) | 0.5 | | |
| Long chain alkyl | about 0.01 to about | about 0.1 to about 0.4 | about 0.2 to about 0.3 |
| quaternary | 0.5 | | |
| ammonium | | | |
| compound to | | | |
| fluoride source(s) | | | |

Preferably, the wet clean compositions of the invention are devoid or substantially devoid of added water and added HF. Further, the wet clean compositions are preferably devoid of oxidizing agents, abrasive material, strong acids and strong bases.

The wet clean compositions are easily formulated by simple addition of the respective ingredients and mixing to homogeneous condition. Furthermore, the compositions may be readily formulated as single-package formulations or multi-part formulations that are mixed at the point of use. The individual parts of the multi-part formulation may be mixed at the tool or in a storage tank upstream of the tool. The concentrations of the respective ingredients may be widely varied in specific multiples of the composition, e.g., more dilute or more concentrated, and it will be appreciated that the compositions can variously and alternatively comprise, consist or consist essentially of any combination of ingredients consistent with the disclosure herein. For example, a concentrate may be prepared having the recited weight percent ratios of chelating agent(s) to fluoride source(s) and polymeric species to fluoride source(s) and the user may dilute the composition with glycol solvent(s) until the weight percent ratio of glycol solvent(s) to fluoride source(s) are achieved.

Another aspect relates to a kit including, in one or more containers, one or more components adapted to form the wet clean compositions described herein. The kit may include, in one or more containers, at least one fluoride source, at least one glycol solvent, at least one chelating agent, at least one polymeric species, optionally at least one amine and optionally at least one long chain alkyl quaternary ammonium compound, for combining as is or with diluent (e.g., additional glycol solvent) at the fab.

The containers of the kit should be chemically rated to store and dispense the component(s) contained therein. For example, the containers of the kit may be NOWPak® containers (Advanced Technology Materials, Inc., Danbury, Conn., USA). The one or more containers which contain the components of the removal composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended wet clean composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and U.S. Patent Application No. 60/916,966 entitled “SYSTEMS AND METHODS FOR MATERIAL BLENDING AND DISTRIBUTION” filed on May 9, 2007 in the name of John E. Q. Hughes, and PCT/US08/63276 entitled “SYSTEMS AND METHODS FOR MATERIAL BLENDING AND DISTRIBUTION” filed on May 9, 2008 in the name of Advanced Technology Materials, Inc.

As applied to microelectronic device manufacturing operations, the wet clean compositions of the present invention are usefully employed to (i) selectively remove higher density dielectric material relative (e.g., undoped silicon-containing materials) to lower density dielectric material (e.g., doped silicon-containing materials) from the surface of the microelectronic device, and/or (ii) to remove post-etch and/or post-ash residue from the surface of the microelectronic device wherein the etch rate of undoped silicon-containing materials present on the device is greater than or substantially equal to that of doped silicon-containing materials also present. Importantly, the wet clean compositions of the invention are compatible with the underlying layers, e.g., metal(s) and silicon, also present on the microelectronic device.

It should be appreciated by one skilled in the art that the compositions described herein may be used in a one-step or multi-step removal process. Preferably, the materials to be removed are removed in a single step process.

In the cleaning application, the wet clean composition is applied in any suitable manner to the microelectronic device having the material to be removed thereon, e.g., by spraying the composition on the surface of the device, by dipping (in a volume of the composition) of the device including the material to be removed, by contacting the device with another material, e.g., a pad, or fibrous sorbent applicator element, that has the composition absorbed thereon, by contacting the device including the material to be removed with a circulating composition, or by any other suitable means, manner or technique, by which the wet clean composition is brought into contact with the material to be removed on the microelectronic device. The cleaning application may be static and/or dynamic, as readily determined by one skilled in the art. Moreover, the process may be for a batch or single wafer system. Following contact of the wet clean composition with the material to be removed, the wet clean composition may further include residue materials selected from the group consisting of doped silicon-containing materials, undoped silicon-containing materials, post-etch residue, post-ash residue, and combinations thereof, which may be suspended and/or dissolved in said wet clean composition.

In use of the compositions for removing materials from microelectronic devices having same thereon, the wet clean composition typically is contacted with the surface for a sufficient time of from about 30 sec to about 10 minutes, preferably about 90 sec to 7 min, at sufficient conditions such as temperature in a range of from about 20° C. to about 60° C., preferably about 30-50° C. Such contacting times and temperatures are illustrative, and any other suitable time and temperature conditions may be employed.

Etch targets include, but are not limited to, ThOx, BPSG, PSG, BSG, and SOD. Preferably, etch targets for the current work are ThOx: about 1 Å min⁻¹ to about 20 Å min⁻¹, preferably about 2 Å min⁻¹ to about 10 Å min⁻¹, wherein the selectivity ratio of BPSG to ThOx is in a range from about 0.4:1 to about 1:1, preferably about 0.4:1 to about 0.6:1, the selectivity ratio of PSG to ThOx is in a range from about 0.5:1 to about 2.5:1, preferably about 1:1 to about 1.4:1, and the selectivity ratio of SOD to ThOx is in a range from about 0.5:1 to about 1.4:1, preferably about 1:1 to about 1.4:1, at temperature in a range from about 35° C. to about 50° C., wherein the BPSG comprises 3.6-4.0% B and 3.3-3.7% P, the SOG is organic SOG, and PSG comprises 3.3-3.7% P. The best observed selectivities for the doped and un-doped oxides are 1:1 or lower.

Advantageously, the compositions described herein controllably remove doped and undoped silicon-containing materials. In addition, the compositions have very low amounts of components other than the organic solvent which makes disposal of the compositions easier. For example, the compositions preferably include greater than 99 wt % organic solvent.

The features and advantages of the invention are more fully illustrated by the following non-limiting examples, wherein all parts and percentages are by weight, unless otherwise expressly stated.

### Example 1

Composition A: 0.15 wt % IDA, 0.04 wt % Lupasol® G20, 0.25 wt % ammonium fluoride, 99.56 wt % ethylene glycol

Blanketed BPSG (3000 Å plus anneal, 3.6-4.0% B, 3.3-3.7% P), HDP (6000 Å), TEOS (2000 Å), polySi, ThOx (4000 Å), SOG (organic SOG, 4500 Å), SiN (LPCVD (2000 Å) and PECVD (4000 Å)), W (3000 Å), TiN (1000 Å) and PSG (4500 Å plus anneal, 3.3-3.7% P) were immersed in composition A at 30° C. for the time indicated, without agitation, and the results in Table 1 were obtained. As observed the selectivities for most materials are similar to that of ThOx and based on the resistance, the metals and metal alloys are not affected by the composition.

TABLE 1
Results in Formulation A

| | | | | | Resistance Delta |
|---|---|---|---|---|---|
| Processing | | | Film Etch Rate | Selectivity to | Percent |
| Time (min) | Film | Film Etch (Å) | (Å/min) | ThOx | ([Pre-Post]/Pre) |
| 5 | ThOx | 11.52 | 2.30 | 1.00 | |
| | SiN - PECVD | 9.87 | 1.97 | 0.86 | |
| | SiN - LPCVD | 1.43 | 0.29 | 0.12 | |
| | BPSG | 10.51 | 2.10 | 0.91 | |
| | SOG | 4.76 | 0.95 | 0.41 | |
| | PSG | 35.93 | 7.19 | 3.12 | |
| | TEOS | 14.72 | 2.94 | 1.28 | |
| | HDP | 11.03 | 2.21 | 0.96 | |
| | W | | | | −2.02E−04 |
| | TiN | | | | −8.45E−04 |
| 10 | ThOx | 21.36 | 2.14 | 1.00 | |
| | SiN - PECVD | 16.14 | 1.61 | 0.76 | |
| | SiN - LPCVD | 2.92 | 0.29 | 0.14 | |
| | BPSG | 17.42 | 1.74 | 0.82 | |
| | SOG | 10.49 | 1.05 | 0.49 | |
| | PSG | 52.12 | 5.21 | 2.44 | |
| | TEOS | 22.72 | 2.27 | 1.06 | |
| | HDP | 24.26 | 2.43 | 1.14 | |
| | W | | | | 2.24E−03 |
| | TiN | | | | 1.22E−02 |
| 30 | ThOx | 48.58 | 1.62 | 1.00 | |
| | SiN - PECVD | 30.43 | 1.01 | 0.63 | |
| | SiN - LPCVD | 3.62 | 0.12 | 0.07 | |
| | BPSG | 26.61 | 0.89 | 0.55 | |
| | SOG | 22.14 | 0.74 | 0.46 | |
| | PSG | 108.03 | 3.60 | 2.22 | |
| | TEOS | 55.09 | 1.84 | 1.13 | |
| | HDP | 51.12 | 1.70 | 1.05 | |
| | W | | | | 1.69E−03 |
| | TiN | | | | 2.21E−02 |

### Example 2

Composition B: 0.15 wt % IDA, 0.04 wt % Lupasol® G20, 0.25 wt % ammonium fluoride, 0.06% Aliquat 336 and 99.50 wt % ethylene glycol

Blanketed BPSG (3000 Å plus anneal, 3.6-4.0% B, 3.3-3.7% P), HDP (6000 Å), TEOS (2000 Å), polySi, ThOx (4000 Å), SOG (organic SOG, 4500 Å), SiN (LPCVD (2000 Å) and PECVD (4000 Å)), W (3000 Å), TiN (1000 Å) and PSG (4500 Åplus anneal, 3.3-3.7% P) were immersed in composition B at 30° C. for the indicated time, without agitation, and the results in Table 2 were obtained. As observed the selectivities for most materials were similar to that of ThOx and based on the resistance, the metals and metal alloys are not affected by the composition.

TABLE 2
Results in Formulation B

| | | | | | Resistance Delta |
|---|---|---|---|---|---|
| Processing | | | Film Etch Rate | Selectivity to | Percent |
| Time (min) | Film | Film Etch (Å) | (Å/min) | ThOx | ([Pre-Post]/Pre) |
| 5 | ThOx | 10.54 | 2.11 | 1.00 | |
| | SiN - PECVD | 11.63 | 2.33 | 1.10 | |
| | SiN - LPCVD | 2.99 | 0.60 | 0.28 | |
| | BPSG | 12.49 | 2.50 | 1.19 | |
| | SOG | 4.59 | 0.92 | 0.44 | |
| | PSG | 30.90 | 6.18 | 2.93 | |
| | TEOS | 14.81 | 2.96 | 1.40 | |
| | HDP | 10.55 | 2.11 | 1.00 | |
| | W | | | | 2.08E−03 |
| | TiN | | | | −4.03E−03 |
| 10 | ThOx | 20.06 | 2.01 | 1.00 | |
| | SiN - PECVD | 15.02 | 1.50 | 0.75 | |
| | SiN - LPCVD | 1.35 | 0.14 | 0.07 | |
| | BPSG | 16.20 | 1.62 | 0.81 | |
| | SOG | 8.67 | 0.87 | 0.43 | |
| | PSG | 52.57 | 5.26 | 2.62 | |
| | TEOS | 21.64 | 2.16 | 1.08 | |
| | HDP | 23.69 | 2.37 | 1.18 | |
| | W | | | | 1.97E−03 |
| | TiN | | | | 2.39E−02 |
| 30 | ThOx | 49.41 | 1.65 | 1.00 | |
| | SiN - PECVD | 29.62 | 0.99 | 0.60 | |
| | SiN - LPCVD | 5.13 | 0.17 | 0.10 | |
| | BPSG | 26.48 | 0.88 | 0.54 | |
| | SOG | 59.09 | 1.97 | 1.20 | |
| | PSG | 106.89 | 3.56 | 2.16 | |
| | TEOS | 49.82 | 1.66 | 1.01 | |
| | HDP | 54.10 | 1.80 | 1.10 | |
| | W | | | | 1.27E−03 |
| | TiN | | | | −7.64E−04 |

For comparison, blanketed BPSG (3000 Å plus anneal, 3.6-4.0% B, 3.3-3.7% P), HDP (6000 Å), TEOS (2000 Å), polySi, ThOx (4000 Å), SOG (organic SOG, 4500 Å), SiN (LPCVD (2000 Å) and PECVD (4000 Å)), W (3000 Å), TiN (1000 Å) and PSG (4500 Å plus anneal, 3.3-3.7% P) were immersed in dilute hydrofluoric acid (DHF) at 30° C. for 30 min, without agitation, and the results in Table 3 were obtained.

TABLE 3
Results in DHF

| | | | Selec- | Resistance Delta |
|---|---|---|---|---|
| | Film | Film Etch Rate | tivity to | Percent |
| Film | Etch (Å) | (Å/min) | ThOx | ([Pre-Post]/Pre) |
| ThOx | 779.72 | 25.99 | 1.00 | |
| SiN - PECVD | 1162.47 | 38.75 | 1.49 | |
| SiN - LPCVD | 112.35 | 3.75 | 0.14 | |
| BPSG | 2866.78 | 95.56 | 3.68 | |
| SOG | 3612.05 | 120.40 | 4.63 | |
| PSG | 4592.84 | 153.09 | 5.89 | |
| TEOS | 2070.32 | 69.01 | 2.66 | |
| HDP | 1077.90 | 35.93 | 1.38 | |
| W | | | | 6.59E−04 |
| TiN | | | | −4.23E−03 |

It should be appreciated that although preferably the etch rate of undoped silicon-containing materials is greater than substantially equal to the etch rate of doped silicon-containing materials, there are instances where the doped:undoped etch rate ratio will be greater than 1. For example, the etch rate of PSG:ThOx with DHF was 5.89:1 but it was reduced substantially to 2.16:1 using formulation B. This reduction can be equally advantageous even though the doped:undoped etch rate ratio was still greater than 1:1.

### Example 3

The etch rate of doped polysilicon as a function of low or high energy doping relative to thermal oxide was determined using Formulation B. Samples of As 75 (low)-, As 75 (high)-, P 31 (low)-, P 31 (high)-, BF₂ (low)- and BF₂ (high)-doped polysilicon were immersed in Formulation B at 30° C. for 30 minutes and the etch rates of each determined. The selectivity of each doped material relative to thermal oxide is provided in Table 4, where it can be seen that each film etches at an equivalent or lower rate than thermal oxide.

TABLE 4
Results in Formulation B

| | | | Film Etch Rate | Selectivity to |
|---|---|---|---|---|
| Film | | Film Etch (Å) | (Å/min) | ThOx |
| As 75 low | 5 | 11.09 | 2.22 | 1.05 |
| | 10 | 20.38 | 2.04 | 1.02 |
| | 30 | 51.24 | 1.71 | 1.04 |
| As 75 high | 5 | 16.29 | 3.26 | 1.55 |
| | 10 | 24.38 | 2.44 | 1.22 |
| | 30 | 53.96 | 1.80 | 1.09 |
| P31 low | 5 | 13.39 | 2.68 | 1.27 |
| | 10 | 22.04 | 2.20 | 1.10 |
| | 30 | 54.36 | 1.81 | 1.10 |
| P31 high | 5 | 16.46 | 3.29 | 1.56 |
| | 10 | 25.23 | 2.52 | 1.26 |
| | 30 | 59.43 | 1.98 | 1.20 |
| BF₂ low | 5 | 9.07 | 1.81 | 0.86 |
| | 10 | 15.29 | 1.53 | 0.76 |
| | 30 | 38.72 | 1.29 | 0.78 |
| BF₂ high | 5 | 5.06 | 1.01 | 0.48 |
| | 10 | 7.37 | 0.74 | 0.37 |
| | 30 | 14.85 | 0.50 | 0.30 |
| PolySi undoped | 5 | 10.09 | 2.02 | 0.96 |
| | 10 | 20.10 | 2.01 | 1.00 |
| | 30 | 42.37 | 1.41 | 0.86 |

### Example 4

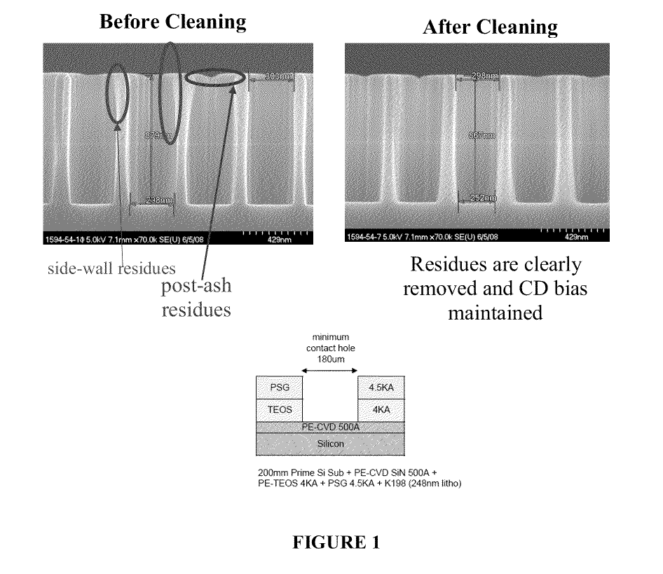

In addition, the post-ash and contact-hole residue removal capability of the formulations was also studied. FIG. 1 illustrates the C/S SEM image of a coupon processed with formulation B at 45° C. for 4 min, which resulted in roughly a 20 Å ThOx removal. The stack structure of the pattern, which consists of a ˜500 Å of PE-CVD SiN base with the “walls” made of 4 KÅ TEOS and 4.5 KÅ PSG is also illustrated in FIG. 1.

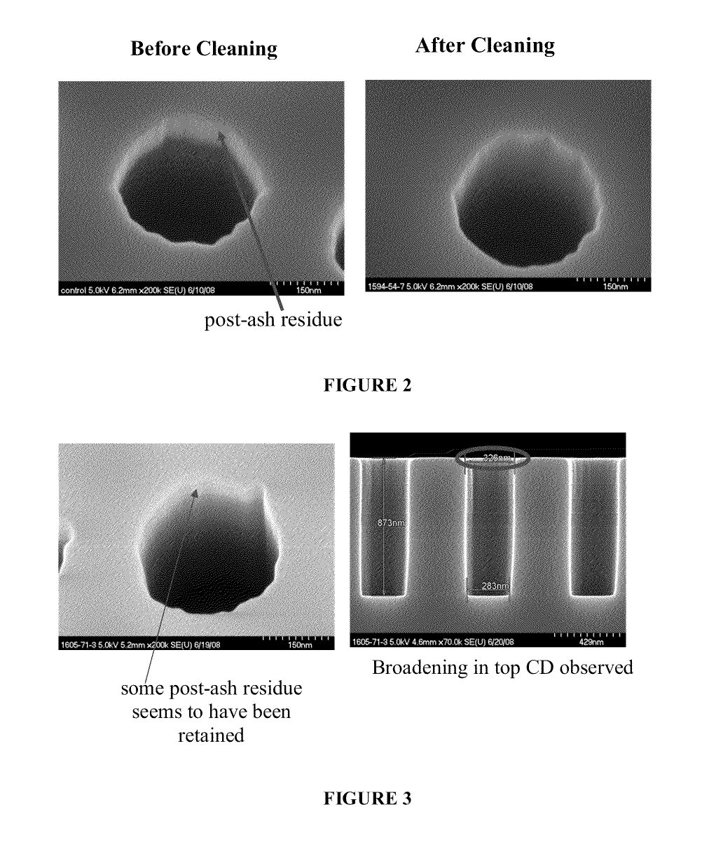

FIGS. 2 and 3 illustrate the C/S SEM images of a coupon of a similar structure that has been cleaned using Formulation B (45° C./4 min) and dilute hydrofluoric acid (DHF) (25° C./4 min), respectively. It can be seen that the coupon cleaned with DHF resulted in roughly a 13.6 Å ThOx removal, the post-ash residue was not completely removed and the CD was deteriorated to some extent.

### Example 5

Additional compositions were formulated, as follows:

Composition C: 0.18 wt % succinic acid, 0.05 wt % Lupasol® G20, 0.30 wt % ammonium fluoride, and 99.47 wt % propylene glycol

Composition D: 0.18 wt % succinic acid, 0.05 wt % Lupasol® G20, 0.15 wt % ammonium fluoride, 0.15 wt % ammonium bifluoride, and 99.47 wt % propylene glycol

Composition E: 0.4 wt % IDA, 0.14 wt % poly(allylamine), 0.70 wt % ammonium fluoride, and 98.76 wt % ethylene glycol

Composition F: 0.4 wt % IDA, 0.14 wt % poly(allylamine), 0.70 wt % ammonium fluoride, 0.2 wt % CTAB, and 98.56 wt % ethylene glycol

Composition G: 0.4 wt % IDA, 0.14 wt % poly(allylamine), 0.70 wt % ammonium fluoride, 0.15 wt % Aliquat 336, and 98.61 wt % propylene glycol

Composition H: 0.2 wt % succinic acid, 0.07 wt % Lupasol® G20, 0.35 wt % ammonium fluoride, 0.10 wt % CTAB, and 99.28 wt % propylene glycol

Accordingly, while the invention has been described herein in reference to specific aspects, features and illustrative embodiments of the invention, it will be appreciated that the utility of the invention is not thus limited, but rather extends to and encompasses numerous other aspects, features, and embodiments. Accordingly, the claims hereafter set forth are intended to be correspondingly broadly construed, as including all such aspects, features, and embodiments, within their spirit and scope.

1. A composition comprising ammonium fluoride, ethylene glycol, iminodiacetic acid, and polyethylenimine polymer.

2. A wet clean composition comprising at least one fluoride source, at least one glycol solvent, at least one chelating agent and at least one polymeric species, wherein the composition is substantially devoid of added water.

3. The composition of claim 2, wherein the at least one fluoride source comprises a species selected from the group consisting of xenon difluoride; pentamethyldiethylenetriammonium trifluoride; ammonium bifluoride; triethylamine trihydrofluoride; alkyl hydrogen fluoride (NRH₃F), wherein each R is independently selected from hydrogen and C₁-C₄ alkyl; dialkylammonium hydrogen fluoride (NR₂H₂F), wherein each R is independently selected from hydrogen and C₁-C₄ alkyl; trialkylammonium hydrogen fluoride (NR₃3HF), wherein each R is independently selected from hydrogen and C₁-C₄ alkyl; trialkylammonium trihydrogen fluoride (NR₃:3HF), wherein each R is independently selected from hydrogen and C₁-C₄ alkyl; ammonium fluorides of the formula R₄NF, wherein each R is independently selected from hydrogen, C₁-C₄ alkyl, and C₁-C₄ alkanol; and combinations thereof.

4. The composition of claim 2, wherein the at least one glycol solvent comprises a glycol solvent selected from the group consisting of ethylene glycol, propylene glycol, diethylene glycol, dipropylene glycol, glycerol, a monoglyceride, a diglyceride, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof.

5.-7. (canceled)

8. The composition of claim 2, wherein the at least one chelating agent comprises a species selected from the group consisting of acetylacetonate, 1,1,1-trifluoro-2,4-pentanedione, 1,1,1,5,5,5-hexafluoro-2,4-pentanedione, formate, acetate, glycine, serine, proline, leucine, alanine, asparagine, aspartic acid, glutamine, valine, lysine, iminodiacetic acid (IDA), malonic acid, oxalic acid, succinic acid, boric acid, nitrilotriacetic acid, malic acid, citric acid, acetic acid, maleic acid, 2,4-pentanedione, benzalkonium chloride, 1-imidazole, phosphonic acid, hydroxyethylidene diphosphonic acid (HEDP), 1-hydroxyethane-1,1-diphosphonic acid, nitrilo-tris(methylenephosphonic acid), etidronic acid, ethylenediamine, ethylenediaminetetraacetic acid (EDTA), (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates, ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid, sodium triphosphate penta basic, and combinations thereof.

9. (canceled)

10. (canceled)

11. The composition of claim 2, wherein the at least one polymeric species comprises at least one species selected from the group consisting of a polypropylenimine dendrimer, a poly(vinyl amine), a polyamine, a polyimidamine, a polyethylimine, a polybutadiene, a polyamidamine, a poly quaternary amine, a polyvinyl amide, a polyacrylamide, a linear polyethylenimine, a branched polyethylenimine, and copolymers comprising the aforementioned homopolymers.

12. The composition of claim 2, wherein the polyethylenimine comprises a species selected from the group consisting of polyethylenimine, an ethylenediamine-ethyleneimine copolymer, a hydroxylated polyethylenimine, a modified polyethylenimine, and combinations thereof.

13. The composition of claim 2, wherein the polymeric species comprises polyethylenimine.

14. The composition of claim 2, further comprising at least one long chain alkyl quaternary ammonium compound selected from the group consisting of a tricapryl methylammonium cation, a trioctyl methyl ammonium cation, a cetyltrimethylammonium cation, a dodecyltrimethyl ammonium cation, a hexadecyltrimethylammonium cation, a dioctyl dimethyl ammonium cation, a poly(allyldimethylammonium) cation, and mixtures thereof.

15. (canceled)

16. (canceled)

17. The composition of claim 14, comprising ammonium fluoride, ethylene glycol, iminodiacetic acid, polyethylenimine polymer, and long chain alkyl quaternary ammonium compound.

18. The composition of claim 2, wherein the composition is substantially devoid of added HF.

19. The composition of claim 2, wherein the composition further comprises residue material selected from the group consisting of: doped silicon-containing material; undoped silicon-containing material; post-etch residue; post-ash residue; and combinations thereof.

20. The composition of claim 2, wherein the composition further comprises residue material selected from the group consisting of thermal oxide (ThOx), TEOS, borophosphosilicate glass (BPSG), phosphosilicate glass (PSG), fluorosilicate glass (FSG), spin-on dielectric (SOD), and combinations thereof.

21. The composition of claim 2, wherein the pH is in a range from about 4 to about 9.

22. A method of selectively removing undoped silicon-containing material relative to doped silicon-containing material, said method comprising contacting a microelectronic device having undoped and doped silicon-containing materials thereon with a wet clean composition under contacting conditions, wherein the wet clean composition comprises the wet clean composition of claim 2.

23. A method of removing post-etch and/or post-ash residue from a microelectronic device, said method comprising contacting a microelectronic device having post-etch and/or post-ash residue thereon with a wet clean composition under contacting conditions, wherein the wet clean composition comprises at least one fluoride source, at least one glycol solvent, at least one chelating agent and at least one polymeric species, and wherein the etch rate of undoped silicon-containing materials present on said device is greater than or substantially equal to the etch rate of doped silicon-containing materials present on said device, and wherein the composition is substantially devoid of water.

24. The method of claim 22, wherein the at least one fluoride source comprises a species selected from the group consisting of xenon difluoride; pentamethyldiethylenetriammonium trifluoride; ammonium bifluoride; triethylamine trihydrofluoride; alkyl hydrogen fluoride (NRH₃F), wherein each R is independently selected from hydrogen and C₁-C₄ alkyl; dialkylammonium hydrogen fluoride (NR₂H₂F), wherein each R is independently selected from hydrogen and C₁-C₄ alkyl; trialkylammonium hydrogen fluoride (NR₃HF), wherein each R is independently selected from hydrogen and C₁-C₄ alkyl; trialkylammonium trihydrogen fluoride (NR₃:3HF), wherein each R is independently selected from hydrogen and C₁-C₄ alkyl; ammonium fluorides of the formula R₄NF, wherein each R is independently selected from hydrogen, C₁-C₄ alkyl, and C₁-C₄ alkanol; and combinations thereof,
wherein the at least one glycol solvent comprises a glycol solvent selected from the group consisting of ethylene glycol, propylene glycol, diethylene glycol, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof,
wherein the at least one chelating agent comprises a species selected from the group consisting of acetylacetonate, 1,1,1-trifluoro-2,4-pentanedione, 1,1,1,5,5,5-hexafluoro-2,4-pentanedione, formate, acetate, glycine, serine, proline, leucine, alanine, asparagine, aspartic acid, glutamine, valine, lysine, iminodiacetic acid (IDA), malonic acid, oxalic acid, succinic acid, boric acid, nitrilotriacetic acid, malic acid, citric acid, acetic acid, maleic acid, 2,4-pentanedione, benzalkonium chloride, 1-imidazole, phosphonic acid, hydroxyethylidene diphosphonic acid (HEDP), 1-hydroxyethane-1,1-diphosphonic acid, nitrilo-tris(methylenephosphonic acid), etidronic acid, ethylenediamine, ethylenediaminetetraacetic acid (EDTA), (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates, ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid, sodium triphosphate penta basic, and combinations thereof, and
wherein the at least one polymeric species comprises at least one species selected from the group consisting of a polypropylenimine dendrimer, a poly(vinyl amine), a polyamine, a polyimidamine, a polyethylimine, a polybutadiene, a polyamidamine, a poly quaternary amine, a polyvinyl amide, a polyacrylamide, a linear polyethylenimine, a branched polyethylenimine, and copolymers of the aforementioned homopolymers.

25. The method of claim 23, wherein the at least one fluoride source comprises a species selected from the group consisting of xenon difluoride; pentamethyldiethylenetriammonium trifluoride; ammonium bifluoride; triethylamine trihydrofluoride; alkyl hydrogen fluoride (NRH₃F), wherein each R is independently selected from hydrogen and C₁-C₄ alkyl; dialkylammonium hydrogen fluoride (NR₂H₂F), wherein each R is independently selected from hydrogen and C₁-C₄ alkyl; trialkylammonium hydrogen fluoride (NR₃HF), wherein each R is independently selected from hydrogen and C₁-C₄ alkyl; trialkylammonium trihydrogen fluoride (NR₃:3HF), wherein each R is independently selected from hydrogen and C₁-C₄ alkyl; ammonium fluorides of the formula R₄NF, wherein each R is independently selected from hydrogen, C₁-C₄ alkyl, and C₁-C₄ alkanol; and combinations thereof,
wherein the at least one glycol solvent comprises a glycol solvent selected from the group consisting of ethylene glycol, propylene glycol, diethylene glycol, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof,
wherein the at least one chelating agent comprises a species selected from the group consisting of acetylacetonate, 1,1,1-trifluoro-2,4-pentanedione, 1,1,1,5,5,5-hexafluoro-2,4-pentanedione, formate, acetate, glycine, serine, proline, leucine, alanine, asparagine, aspartic acid, glutamine, valine, lysine, iminodiacetic acid (IDA), malonic acid, oxalic acid, succinic acid, boric acid, nitrilotriacetic acid, malic acid, citric acid, acetic acid, maleic acid, 2,4-pentanedione, benzalkonium chloride, 1-imidazole, phosphonic acid, hydroxyethylidene diphosphonic acid (HEDP), 1-hydroxyethane-1,1-diphosphonic acid, nitrilo-tris(methylenephosphonic acid), etidronic acid, ethylenediamine, ethylenediaminetetraacetic acid (EDTA), (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates, ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid, sodium triphosphate penta basic, and combinations thereof, and
wherein the at least one polymeric species comprises at least one species selected from the group consisting of a polypropylenimine dendrimer, a poly(vinyl amine), a polyamine, a polyimidamine, a polyethylimine, a polybutadiene, a polyamidamine, a poly quaternary amine, a polyvinyl amide, a polyacrylamide, a linear polyethylenimine, a branched polyethylenimine, and copolymers of the aforementioned homopolymers.

26. (canceled)

27. (canceled)

28. The method of claim 22, wherein the contacting conditions comprise: time in a range from about 30 sec to about 10 min; temperature in a range from about 20° C. to about 60° C.; and combinations thereof.

29. The method of claim 22, wherein the undoped silicon-containing materials comprises thermal oxide, and wherein the etch rate of thermal oxide is in a range from about 1 Å min⁻¹ to about 20 Å min⁻¹.
